(19) United States
(12) Patent Application Publication
(10) Pub. No.: US 2022/0214627 A1
(43) Pub. Date: Jul. 7, 2022

(54) ASSEMBLY IN AN OPTICAL SYSTEM, IN PARTICULAR OF A MICROLITHOGRAPHIC PROJECTION EXPOSURE APPARATUS

(71) Applicant: Carl Zeiss SMT GmbH, Oberkochen (DE)

(72) Inventors: Joachim Hartjes, Aalen (DE); Toralf Gruner, Aalen-Hofen (DE); Alexander Wolf, Essingen (DE)

(21) Appl. No.: 17/704,559

(22) Filed: Mar. 25, 2022

Related U.S. Application Data
(63) Continuation of application No. PCT/EP2020/072485, filed on Aug. 11, 2020.

(30) Foreign Application Priority Data
Oct. 23, 2019 (DE) 102019216301.7

(51) Int. Cl. G03F 7/20

(52) U.S. Cl. CPC G03F 7/70891; G03F 7/7085; G03F 7/702

(57) ABSTRACT

An assembly in an optical system, such as a microlithographic projection exposure apparatus, includes an optical element, at least one cooling channel through which can flow a cooling fluid for cooling the optical element during the operation of the optical system, and at least one corrosion detector for detecting an existing or imminent corrosion on the basis of the determination of at least one measurement variable indicating a corrosion-dictated change in state of the cooling fluid.

### CROSS-REFERENCE TO RELATED APPLICATIONS

The present application is a continuation of, and claims benefit under 35 USC 120 to, international application PCT/EP2020/072485, filed Aug. 11, 2020, which claims benefit under 35 USC 119 of German Application No. 10 2019 216 301.7, filed Oct. 23, 2019. The entire disclosure of these applications are incorporated by reference herein.

### FIELD

The disclosure relates to an assembly in an optical system, such as a microlithographic projection exposure apparatus.

### BACKGROUND

Microlithography is used for production of microstructured components, for example integrated circuits or LCDs. The microlithography process is conducted in what is called a projection exposure apparatus, which includes an illumination device and a projection lens. The image of a mask (=reticle) illuminated using the illumination device is in this case projected using the projection lens onto a substrate (for example, a silicon wafer) coated with a light-sensitive layer (photoresist) and arranged in the image plane of the projection lens, in order to transfer the mask structure to the light-sensitive coating of the substrate.

In projection lenses designed for the EUV range, i.e., at wavelengths of, for example, approximately 13 nm or approximately 7 nm, mirrors are used as optical components for the imaging process owing to the general lack of availability of suitable light-transmissive refractive materials.

One issue which can arise in practice is that, for example as a result of the absorption of the radiation emitted by the EUV light source, the EUV mirrors heat up and thus undergo an associated thermal expansion or deformation, which in turn can negatively affect the imaging properties of the optical system. This can be the case for example if illumination settings with comparatively small illumination poles are used (for example in dipole or quadrupole illumination settings), in which the mirror heating or deformation can vary greatly over the optical effective surface of the mirror.

Approaches for overcoming the above-described mirror heating known from VUV lithography systems (with an operating wavelength of approximately 200 nm or approximately 160 nm, for example) to EUV systems can be difficult in part insofar as, inter alia, the number of optical effective surfaces available for active deformation compensation is relatively tightly delimited as a consequence of the comparatively smaller number of optical elements or mirrors (for avoiding excessively high light losses on account of the reflections involved).

Known approaches for dissipating thermal loads from optical components, such as of a microlithographic projection exposure apparatus include, inter alia, the use of cooling channels through which a cooling fluid such as water, for example, flows in order to carry away heat and which are connected to an inlet and an outlet for the cooling fluid.

In practice, however, depending on the structural configuration of the cooling channels (which can extend for example on the mirror rear side or in a mechanical carrying structure), corrosion-dictated damage caused by the cooling fluid can occur within the cooling lines themselves and/or in the region of flange connections and then result in a limitation of the service life of the assembly. For example, in the case where the assembly is constructed from components that are separated from one another, the cooling fluid can flow over a gap present between such components and cause corrosion-dictated leaks in the region of the flange connections. Given the occurrence of corrosion-dictated leaks, ingress of cooling liquid into the respective optical system can result in serious damage.

Avoiding the corrosion-dictated issues described above can be difficult in practice because, inter alia, for example carrying out ultrasonic measurements for corrosion detection in an EUV system is typically ruled out owing to the risk of layer detachments at the optical components.

### SUMMARY

The present disclosure seeks to provide an assembly in an optical system, for example of a microlithographic projection exposure apparatus, which makes it possible to effectively avoid corrosion-dictated issues and thus accompanying damage of the optical system.

In an aspect, the disclosure provides an assembly in an optical system, such as a microlithographic projection exposure apparatus. The assembly includes: an optical element; at least one cooling channel through which can flow a cooling fluid for cooling the optical element during the operation of the optical system; and at least one corrosion detector for detecting an existing or imminent corrosion on the basis of the determination of at least one measurement variable indicating a corrosion-dictated change in state of the cooling fluid.

The disclosure involves the concept of ascertaining incipient corrosion and initiating, at a correspondingly early stage, suitable countermeasures on the basis of a detection of corrosion-dictated changes in state of the cooling liquid situated within at least one cooling channel of the assembly.

In accordance with one embodiment, the at least one measurement variable includes an electrical conductivity of the cooling fluid.

In accordance with one embodiment, the corrosion detector is configured for detecting an existing or imminent corrosion on the basis of a non-contact inductive conductivity measurement of the cooling fluid.

The disclosure thus includes, for example, the concept of deducing incipient corrosion on the basis of a non-contact inductive conductivity measurement of the cooling fluid. This involves detecting the ionization state or electrical conductivity of the cooling fluid metro logically by a procedure in which, upon an AC voltage being applied to a transmitter coil, the electrical voltage measured at a receiver coil is compared with the transmission voltage, wherein an amplitude attenuation or phase shift ascertained during this comparison is indicative of the ionization or conductivity state of the cooling liquid.

In accordance with one embodiment, the corrosion detector is configured for detecting an existing or imminent corrosion on the basis of a magnetoinductive flow measurement. In this case, for example upon a constant external magnetic field being applied to an insulated pipe carrying the electrically conductive cooling liquid, it is possible to measure the change in voltage that accompanies a corrosion-dictated change in the flow velocity on the basis of the Hall effect.

In accordance with one embodiment, the at least one measurement variable includes a flow resistance of the cooling fluid.

In accordance with one embodiment, the at least one measurement variable includes dynamic excitations or vibrations that are caused by a corrosion-dictated change in the flow state of the cooling fluid.

In accordance with one embodiment, the at least one measurement variable includes a proportion of indicator molecules or particles present in the cooling fluid, wherein a presence of the molecules or particles in the cooling fluid indicates that they have been dissolved from a material of the assembly in a corrosion-dictated manner.

In accordance with one embodiment, the assembly has a plurality of corrosion detectors for spatially resolved corrosion detection that are arranged at different positions.

Furthermore, the disclosure also includes the concept of realizing a combination of the measures mentioned above. This can be done, for example, in such a way that firstly the presence of corrosion at all is ascertained (but still without specific location information) by way of the non-contact inductive conductivity measurement and then a spatially resolved corrosion detection is obtained on the basis of a magnetoinductive flow measurement by ascertaining zonal variations of the flow velocity with the aid of detectors or sensors, respectively, that are arranged at suitable positions (for example corrosion-critical locations such as cooling liquid diverting points and flange connections).

The disclosure also includes the concept, for example, of ascertaining incipient corrosion not just by analysing the cooling liquid at an external apparatus (such as for example in the region where coolant is processed), but using a suitable measurement at suitable positions in the region of the element itself that is to be cooled.

In accordance with one embodiment, the optical element is a mirror or a mirror array including a plurality of mirror elements.

In accordance with one embodiment, the optical element is designed for an operating wavelength of less than 30 nm, for example less than 15 nm. However, the disclosure is not limited thereto, and so the disclosure can also be realized advantageously in further applications in an optical system having an operating wavelength in the VUV range (for example of less than 200 nm or less than 160 nm).

The disclosure further relates to an optical system of a microlithographic projection exposure apparatus, for example an illumination device or a projection lens, including at least one assembly having the features described above.

The disclosure further also relates to a method for operating an optical system, for example of a microlithographic projection exposure apparatus, wherein the optical system has an assembly including at least one optical element and at least one cooling channel through which can flow a cooling fluid for cooling the optical element during the operation of the optical system, wherein the method includes the steps of: a) detecting an existing or imminent corrosion on the basis of the determination of at least one measurement variable indicating a corrosion-dictated change in state of the cooling fluid; and b) carrying out, in reaction to the detection of an existing or imminent corrosion, a countermeasure for avoiding corrosion-dictated damage to the optical system by the cooling fluid.

Carrying out the countermeasure can include, for example, at least one of the following steps: exchanging a component of the optical system; sealing the cooling channel; and setting or interrupting cooling operation of the optical system.

In accordance with one embodiment, the assembly is configured in accordance with the features described above.

Further configurations of the disclosure can be gathered from the description and the claims.

### BRIEF DESCRIPTION OF THE DRAWINGS

The disclosure is explained in greater detail below on the basis of exemplary embodiments illustrated in the accompanying figures, in which:

FIG. 1 shows a schematic illustration for elucidating the construction of an assembly in accordance with one embodiment of the disclosure;

FIG. 2 shows a diagram for elucidating a possible evaluation of measurement results obtained in the assembly from FIG. 1;

FIG. 3 shows a schematic illustration for elucidating the construction of an assembly in accordance with a further embodiment of the disclosure; and

FIG. 4 shows a schematic illustration for elucidating the possible construction of a microlithographic projection exposure apparatus designed for operation in the EUV.

### DETAILED DESCRIPTION OF PREFERRED EMBODIMENTS

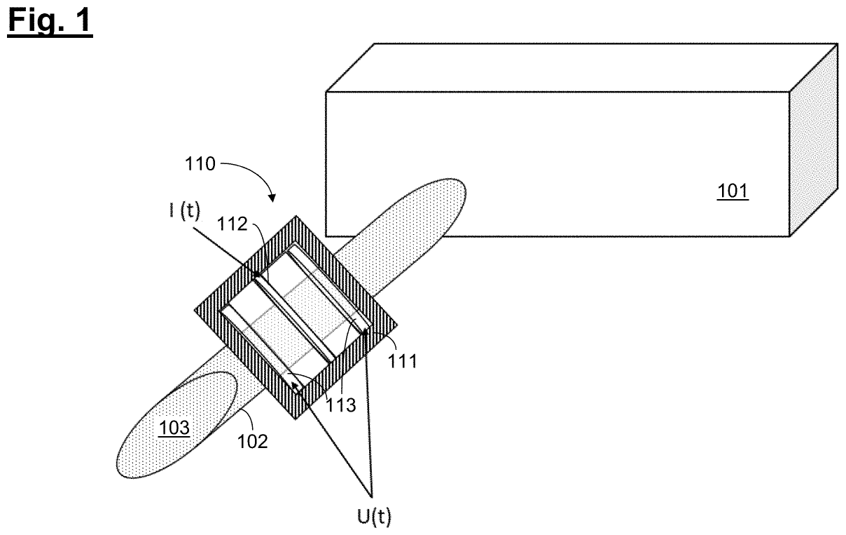

Possible embodiments of an assembly according to the disclosure are described below with reference to the schematic illustrations of FIGS. 1-3.

In FIG. 1, “101” denotes a structure to be cooled in the assembly according to the disclosure. the structure to be cooled can have for example a heat sink serving as a carrier for at least one optical element (not illustrated), within which heat sink there is provided a cooling channel through which a cooling fluid 103 such as for example water flows during operation. The cooling channel has an inlet and an outlet for the cooling fluid 103 and is connected to a corresponding cooling fluid source for realizing a closed cooling circuit. “102” denotes a cooling line connected to the at least one cooling channel.

The heat sink can be produced from any suitable material having good thermal conduction such as for example steel, aluminium or copper. A component forming the cooling channel can be produced from the same or another suitable material, in principle.

The optical element can be—without the disclosure being restricted thereto—a mirror or a mirror array (for example a facet mirror) of a microlithographic projection exposure apparatus designed for operation in the EUV. However, the disclosure is also advantageously usable, in principle, in any other applications (including outside lithography) in which the intention is to realize effective dissipation of heat while avoiding the corrosion-dictated issues described in the introduction.

What the embodiments described below have in common is that during the operation of the assembly or of the optical system having the assembly, an existing or imminent corrosion is detected on the basis of the determination of at least one measurement variable indicating a corrosion-dictated change in state of the cooling fluid 103. For this purpose, the assembly according to the disclosure has at least one corrosion detector, which can be configured in various ways depending on the type of measurement variable used as indicative of the existing or imminent corrosion.

In accordance with the exemplary embodiment in FIG. 1, a corrosion detector designated by “110” in the region of the coolant feed or the cooling line 102 connected to the at least one cooling channel has a transmitter coil 112 and receiver coils 113 in a housing 111 in order to establish an impedance measuring system. The impedance measuring system provided by the corrosion detector 110 in accordance with FIG. 1 makes it possible to detect the ionization state or the electrical conductivity of the cooling fluid 103 metrologically using a comparison between the transmission voltage generated by the transmitter coil 112 (or the electric current I(t) flowing through the transmitter coil 112) and the receiver voltage occurring at the receiver coils 113.

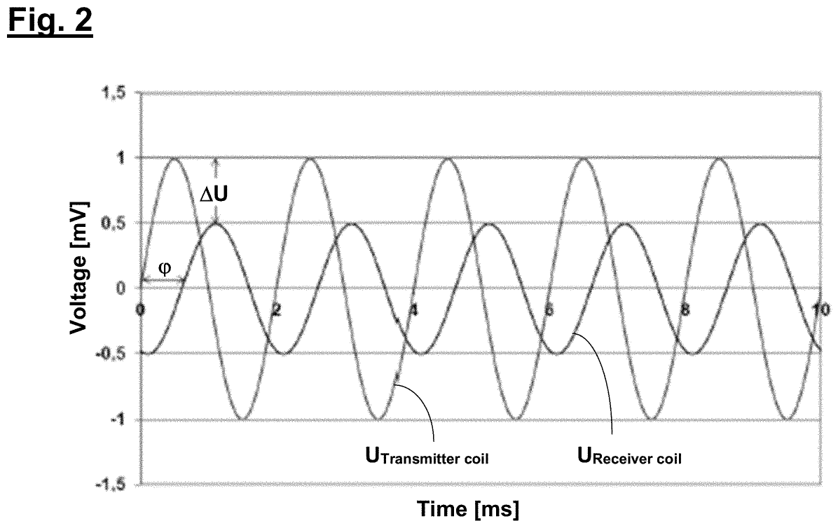

FIG. 2 shows an exemplary diagram of time-dependent voltage profiles, the amplitude attenuation and phase shift measurable between transmission voltage and receiver voltage being used as an indicator of the electrical conductivity and thus the (corrosion) state of the cooling liquid.

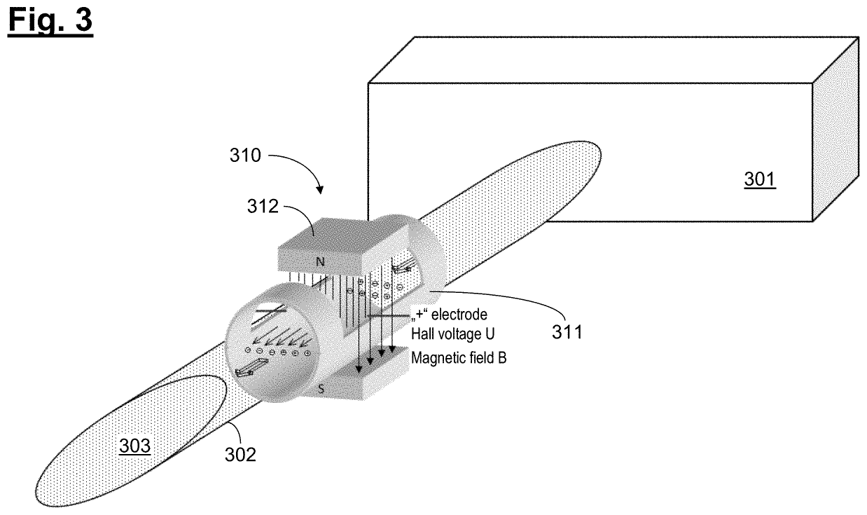

FIG. 3 shows, in a schematic illustration, a further possible construction of an assembly according to the disclosure, wherein analogous or substantially functionally identical components in comparison with FIG. 1 are designated by reference numerals increased by “200”. In accordance with FIG. 3, in contrast to FIG. 1, a magnetoinductive flow measurement on the basis of the Hall effect is carried out. In this case, using a magnet arrangement 312, a homogenous magnetic field is applied to an insulated pipe 311 surrounding the cooling line 302, wherein the electrical voltage proportional to the strength of the magnetic field and the flow velocity is measured. The flow velocity of the cooling fluid 303 can thus be deduced from this measured electrical voltage. The following holds true here:

$$U = B \cdot d \cdot v \qquad ( 1 )$$

where U denotes the electrical voltage, B denotes the magnetic field, d denotes the distance between electrodes (i.e. the diameter of the insulated pipe 311) and v denotes the velocity of the ions (that is to say the flow velocity of the cooling fluid 303).

In further embodiments, it is possible—in addition or as an alternative to the determination of the measurement variables described with reference to FIG. 1 and FIG. 3, respectively, for the use of corresponding corrosion detectors—also to determine further measurement variables indicating a corrosion-dictated change in state of the cooling fluid. By way of example, sound excitations caused by corrosion-induced turbulence and other flow characteristics of the cooling fluid can also be detected by corresponding acoustic detectors. In further embodiments, additionally or alternatively, a permanent or sampling-like chemical analysis of the cooling fluid with regard to the presence of indicator molecules or particles dissolved from a material of the assembly in the event of corrosion (for example iron ions) can also be carried out in an automated manner.

In accordance with a further aspect of the disclosure, the corrosion detection according to the disclosure can also be effected in a spatially resolved manner, by virtue of corresponding corrosion detectors being arranged for example at positions that are relatively important with regard to corrosion, such as for example flange connections. In this case, according to the disclosure, for example, in a first (non-spatially resolved) step by way of a conductivity measurement in accordance with FIG. 1 the existence or imminence of corrosion at all can be determined, whereupon the exact position within the assembly at which the relevant corrosion has occurred or is imminent is determined in a second, spatially resolved step (for example by determining a zonal variation of the flow velocity) with a set-up in accordance with FIG. 3.

In practice, a simulation model or mathematical model can be stored in the cooler design, which model is used to calculate, on the basis of CFD simulations (CFD=“Computed Fluid Dynamics”), the flow changes or turbulence caused by corrosion at significant locations equipped with sensors or corrosion detectors. This model can be verified with test subjects, such that measurement data can be compared with the expected values.

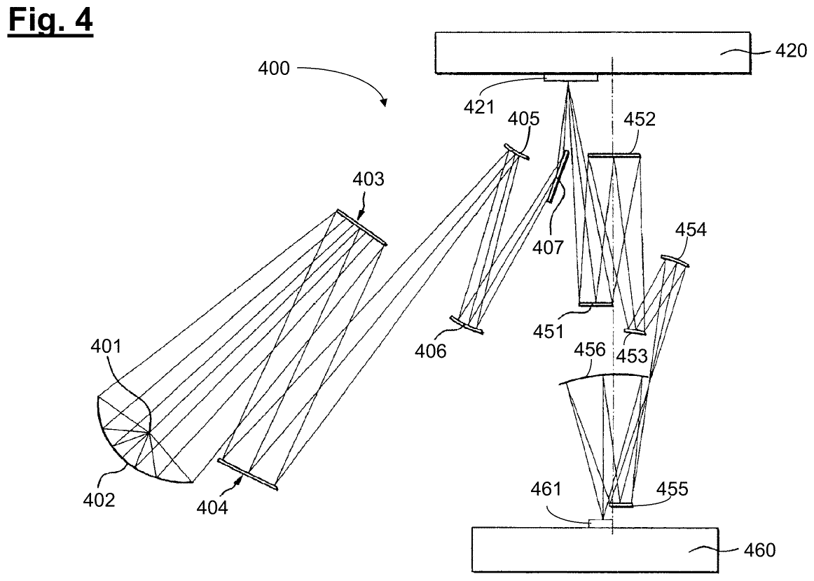

FIG. 4 shows a schematic illustration of an exemplary projection exposure apparatus which is designed for operation in the EUV and in which the present disclosure can be realized by way of example.

According to FIG. 4, an illumination device in a projection exposure apparatus 400 designed for EUV includes a field facet mirror 403 and a pupil facet mirror 404. The light from a light source unit including a plasma light source 401 and a collector mirror 402 is directed onto the field facet mirror 403. A first telescope mirror 405 and a second telescope mirror 406 are arranged in the light path downstream of the pupil facet mirror 404. A deflection mirror 407 is arranged downstream in the light path, the deflection mirror directing the radiation that is incident thereon onto an object field in the object plane of a projection lens including in this case for example six mirrors 451-456. At the location of the object field, a reflective structure-bearing mask 421 is arranged on a mask stage 420, the mask being imaged with the aid of the projection lens into an image plane in which a substrate 461 coated with a light-sensitive layer (photoresist) is situated on a wafer stage 460.

The assembly according to the disclosure can serve for cooling any desired optical element of the projection exposure apparatus 400, for example a mirror or facet mirror within the illumination device or else one of the mirrors of the projection lens.

Even though the disclosure has been described on the basis of specific embodiments, numerous variations and alternative embodiments will be apparent to the person skilled in the art, for example through combination and/or exchange of features of individual embodiments. Accordingly, it goes without saying for the person skilled in the art that such variations and alternative embodiments are also encompassed by the present disclosure, and the scope of the disclosure is restricted only within the meaning of the appended patent claims and the equivalents thereof.

What is claimed is:

1. An assembly, comprising:
an optical element;
a cooling channel configured to have a cooling fluid flow therethrough to cool the optical element; and
a corrosion detector configured to detect an existing or imminent corrosion on the basis of the determination of at least one measurement variable indicating a corrosion-dictated change in state of the cooling fluid.

2. The assembly of claim 1, wherein the at least one measurement variable comprises an electrical conductivity of the cooling fluid.

3. The assembly of claim 1, wherein the corrosion detector is configured to detect an existing or imminent corrosion on the basis of a non-contact inductive conductivity measurement of the cooling fluid.

4. The assembly of claim 1, wherein the at least one measurement variable includes a flow velocity of the cooling fluid.

5. The assembly of claim 1, wherein the corrosion detector is configured to detect an existing or imminent corrosion on the basis of a magnetoinductive flow measurement.

6. The assembly of claim 1, wherein the at least one measurement variable comprises a flow resistance of the cooling fluid.

7. The assembly of claim 1, wherein the at least one measurement variable comprises dynamic excitations or vibrations caused by a corrosion-dictated change in a flow state of the cooling fluid.

8. The assembly of claim 1, wherein the at least one measurement variable comprises a proportion of indicator molecules or particles present in the cooling fluid, and a presence of the indicator molecules or particles in the cooling fluid indicates that they have been dissolved from a material of the assembly in a corrosion-dictated manner.

9. The assembly of claim 1, wherein the assembly comprises a plurality of corrosion detectors configured to spatially resolve corrosion detection, the corrosion detectors being arranged at different positions of the assembly.

10. The assembly of claim 1, wherein the optical element comprises a mirror.

11. The assembly of claim 1, wherein the optical element comprises a mirror array comprising a plurality of mirror elements.

12. The assembly of claim 1, wherein the optical element is configured for an operating wavelength of less than 30 nm.

13. The assembly of claim 1, wherein the optical element is configured for an operating wavelength of less than 15 nm.

14. An apparatus, comprising:
an assembly according to claim 1,
wherein the apparatus is a microlithographic projection exposure apparatus.

15. The apparatus of claim 14, wherein the apparatus comprises an illumination device, and the illumination device comprises the assembly.

16. The apparatus of claim 14, wherein the apparatus comprises a projection lens, and the projection lens comprises the assembly.

17. A method of operating an optical system comprising an assembly which comprises an optical element and a cooling channel configured to have a cooling fluid flow therethrough to cool the optical element, the method comprising:
detecting an existing or imminent corrosion on the basis of the determination of at least one measurement variable indicating a corrosion-dictated change in state of the cooling fluid; and
in response to a detected existing or imminent corrosion, performing a countermeasure to avoid corrosion-dictated damage to the optical system by the cooling fluid.

18. The method of claim 17, wherein the countermeasure comprises at least one member selected from the group consisting of exchanging a component of the optical system, sealing the cooling channel, and setting or interrupting cooling operation of the optical system.

19. The method of claim 17, wherein the assembly further comprises a corrosion detector configured to detect the existing or imminent corrosion on the basis of the determination of the at least one measurement variable indicating the corrosion-dictated change in state of the cooling fluid.

20. The method of claim 17, wherein the assembly is a microlithographic projection exposure apparatus.
